(19) United States
(12) Patent Application Publication
(10) Pub. No.: US 2013/0160949 A1
(43) Pub. Date: Jun. 27, 2013

(54) PLASMA PROCESSING APPARATUS

(71) Applicants: Yusaku SAKKA, Shunan (JP); Ryoji NISHIO, Kudamatsu (JP); Tadayoshi KAWAGUCHI, Kudamatsu (JP)

(72) Inventors: Yusaku SAKKA, Shunan (JP); Ryoji NISHIO, Kudamatsu (JP); Tadayoshi KAWAGUCHI, Kudamatsu (JP)

(73) Assignee: Hitachi High-Technologies Corporation

(21) Appl. No.: 13/570,471

(22) Filed: Aug. 9, 2012

(30) Foreign Application Priority Data
Dec. 21, 2011 (JP) 2011-279149

(51) Int. Cl. H01L 21/3065

(52) U.S. Cl. 156/345.48

(57) ABSTRACT

A plasma processing apparatus which includes a plasma processing chamber for plasma-processing a sample, an induction antenna disposed outside the plasma processing chamber, a radio-frequency power supply for supplying radio-frequency power to the induction antenna, and a unit for controlling electrostatic capacity including a Faraday shield capacitively coupled with plasma and a dielectric window allowing an induction magnetic field to transmit into the plasma processing chamber is provided; electrostatic capacity between the Faraday shield and the dielectric window at a center portion and electrostatic capacity between the Faraday shield and the dielectric window at an edge portion are controlled.

### BACKGROUND OF THE INVENTION

The present invention relates to a plasma processing apparatus and, particularly, to an inductively coupled plasma processing apparatus.

In fabrication of semiconductor devices, an inductively coupled plasma etching apparatus in which an induction magnetic field is generated by letting a radio-frequency current flow through an induction antenna arranged outside a plasma processing chamber to create plasma of a process gas supplied into the plasma processing chamber is used for a technique of surface treatment by plasma etching.

In general, when a sample on which semiconductor devices are formed is plasma-etched in a plasma etching apparatus, a reaction product 7 is generated and is deposited inside the plasma processing chamber. When deposition of the reaction product 7 becomes excessive, the deposits of the reaction product 7 flake off from the inner wall surface of the plasma processing chamber, for example, and may cause generation of contaminating matters. Therefore, plasma cleaning is usually carried out to remove the deposits deposited inside the plasma processing chamber with a proper frequency when samples are plasma-processed in the plasma etching apparatus.

As plasma cleaning in an inductively coupled plasma etching apparatus, JP-A-2004-235545, for example, discloses plasma cleaning for mainly removing the deposits deposited on an inner wall of a window by supplying radio-frequency power to a Faraday shield installed between the induction antenna and the window. When the distribution of the deposits on the window inner wall is not uniform between a center portion and an edge portion of the window inner surface as shown in FIG. 1, however, with the above-described plasma cleaning it is difficult to achieve both removal of the deposits and suppression of etching of the window at once. As a measure to solve this problem, disclosed in JP-A-2005-259836, for example, is a means capable of achieving both removal of reaction products remaining on the chamber inner wall and suppression of etching of a top plate at once by respectively supplying radio-frequency power to divided Faraday shields and optimizing the respective radio-frequency power.

### SUMMARY OF THE INVENTION

For the distribution of deposits as shown in FIG. 1, however, the deposits 5 at the border part of an edge portion of the window 1 and the chamber 2 as shown in FIG. 2 are likely to remain even when the plasma processing chamber is subjected to plasma cleaning by the means disclosed in JP-A-2005-259836. This is because only the edge portion of the window 1 is taken into consideration in JP-A-2005-259836 but removal of the deposits at the border part of the window 1 and the chamber 2 is not considered.

In view of the problem described above, therefore, according to the present invention a plasma processing apparatus capable of conducting plasma cleaning for sufficiently removing deposits inside a plasma processing chamber is provided.

According to the present invention, provided is a plasma processing apparatus including a plasma processing chamber for plasma-processing a sample, an induction antenna disposed outside the plasma processing chamber, a radio-frequency power supply for supplying radio-frequency power to the induction antenna, and a unit including a Faraday shield capacitively coupled with plasma and a dielectric window which seals an upper part of the plasma processing chamber air-tightly and allows an induction magnetic field generated from the induction antenna transmit into the plasma processing chamber to control electrostatic capacity between the Faraday shield and the dielectric window at a center portion and electrostatic capacity between the Faraday shield and the dielectric window at an edge portion.

According to the present invention, also provided is a plasma processing apparatus including a plasma processing chamber for plasma-processing a sample, an induction antenna disposed outside the plasma processing chamber, a radio-frequency power supply for supplying radio-frequency power to the induction antenna, a Faraday shield capacitively coupled with plasma, and a dielectric window for sealing an upper part of the plasma processing chamber air-tightly and allowing an induction magnetic field generated from the induction antenna transmit into the plasma processing chamber, wherein a distance from the Faraday shield to the dielectric window at the center portion and a distance from the Faraday shield to the dielectric window at the edge portion are different from each other.

According to the present invention, further provided is a plasma processing apparatus including a plasma processing chamber for plasma-processing a sample, an induction antenna disposed outside the plasma processing chamber, a radio-frequency power supply for supplying radio-frequency power to the induction antenna, and a unit for controlling a sheath thickness of plasma at a center portion and a sheath thickness of plasma at an edge portion.

According to the present invention, plasma cleaning capable of sufficiently removing deposits inside a plasma processing chamber can be carried out.

Other objects, features, and advantages of the invention will become apparent from the following description of the embodiments of the invention taken in conjunction with the accompanying drawings.

### BRIEF DESCRIPTION OF THE DRAWINGS

FIG. 1 is a diagram showing a distribution of deposits in an inductively coupled plasma etching apparatus according to a related art;

FIG. 2 is a diagram showing deposits at a border part of an edge portion of a window 1 and a chamber 2;

FIG. 3 is a diagram showing positions at which chips of an alumina (Al₂O₃) film are bonded to a wafer;

FIG. 4 is a graph showing removal rate dependencies of the alumina film on an FSV (Faraday Shield Voltage);

FIG. 5 is a chart showing sheath distributions in a plasma processing chamber;

FIG. 6 is a chart showing distributions of ion energy and the number of ions with respect to a radial direction in the plasma processing chamber;

FIG. 7 is a chart showing a distribution of an electric field generated immediately below the window;

FIG. 8 is a chart showing a sheath distribution when the FSV of 1,000 V is applied according to the present invention;

FIG. 9 is a cross-section of an inductively coupled plasma etching apparatus according to the present invention;

FIG. 10 is a top view when the inductively coupled plasma etching apparatus according to the present invention is viewed from the side of an induction antenna;

FIG. 11 is a diagram showing a shape of a Faraday shield 10;

FIG. 12 is a chart showing a sheath distribution when the Faraday shield 10 is applied;

FIG. 13 is a diagram showing an example where a member 17 is inserted into an open end of the Faraday shield 10;

FIG. 14 is a diagram showing a shape of a Faraday shield 20;

FIG. 15 is a diagram showing an example where a member 21 is inserted into an open end of the Faraday shield 20;

FIG. 16 is a diagram showing a shape of a window 16;

FIG. 17 is a diagram showing an example where a member 22 is inserted into an open end of the window 16; and

FIG. 18 is a diagram showing an example of a combination of the Faraday shield 10 and the window 16.

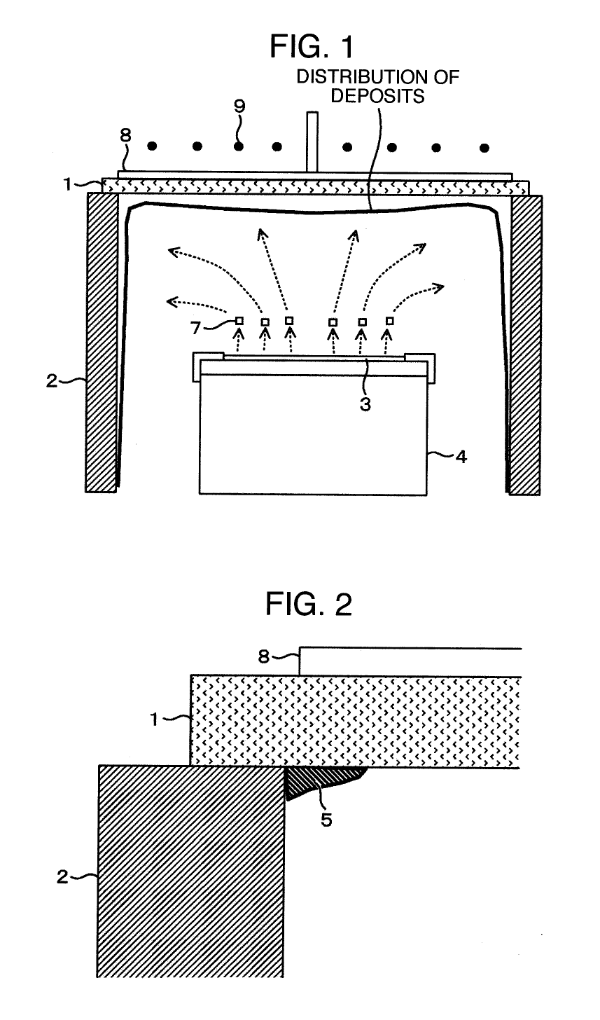

### DESCRIPTION OF THE EMBODIMENTS

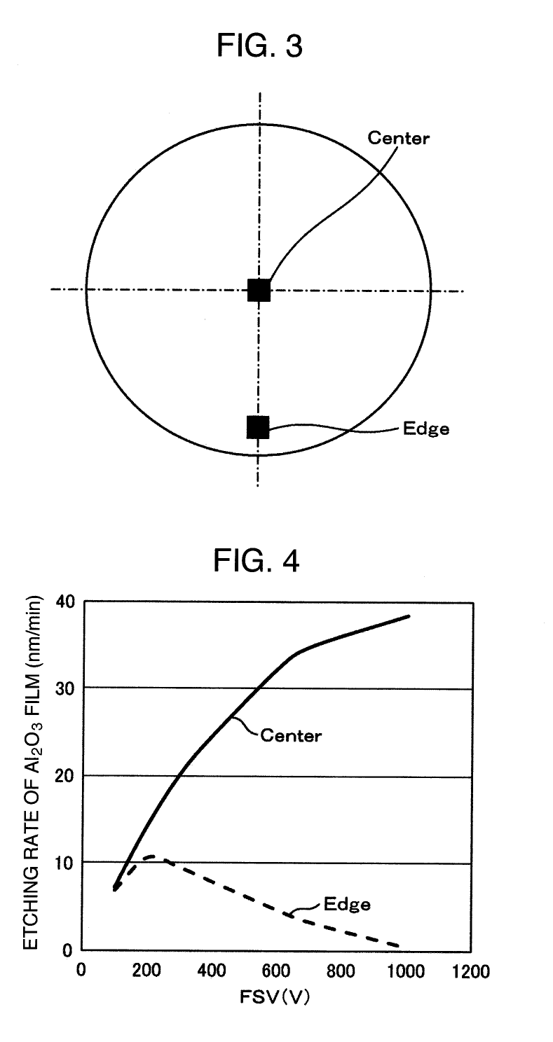

First of all, in order to investigate reasons why removal of deposits at the position as shown in FIG. 2 is difficult, chips of an alumina (Al₂O₃) film are bonded to a wafer at respective positions opposing a center portion (hereinafter called a “Center portion”) and a circumferential portion (hereinafter called an “Edge portion”) of an inner surface of a window 1 which is exposed to plasma as shown in FIG. 3 so that a dependency of a removal rate of the alumina film by plasma cleaning on a radio-frequency voltage applied to a Faraday shield 8 (hereinafter called an “FSV”) is examined. Incidentally, the circumferential portion of the inner surface of the window 1 is the position corresponding to the one where deposits remain as shown in FIG. 2.

As shown in FIG. 4, while the dependency of the removal rate of the alumina film on the FSV at the Center portion exhibits a monotonic increase of the removal rate of the alumina film with the increase of the FSV, the dependency of the removal rate of the alumina film on the FSV at the Edge portion shows a peak in the removal rate of the alumina film when the FSV is 200 V and above 200 V the removal rate of the alumina film decreases monotonically as the FSV increases.

The removal rate of the deposits and the removal rate of the alumina film in plasma cleaning have a positive correlation and the FSV of 400 V or higher is used in ordinary plasma cleaning. Therefore, when a high FSV is applied uniformly in the plane of the Faraday shield 8, the removal rate of the deposits by plasma cleaning at the Edge portion is lower than that at the Center portion on the inner surface of the window 1. For this reason, it is believed that the removal of the deposits in the vicinity of the border part of the Edge portion of the window 1 and the chamber 2 as shown in FIG. 2 becomes difficult.

Further, regarding the trend of monotonic decrease of the removal rate of the alumina film at the Edge portion at the FSV of above 200 V with the increase of the FSV it can be conceived as follows.

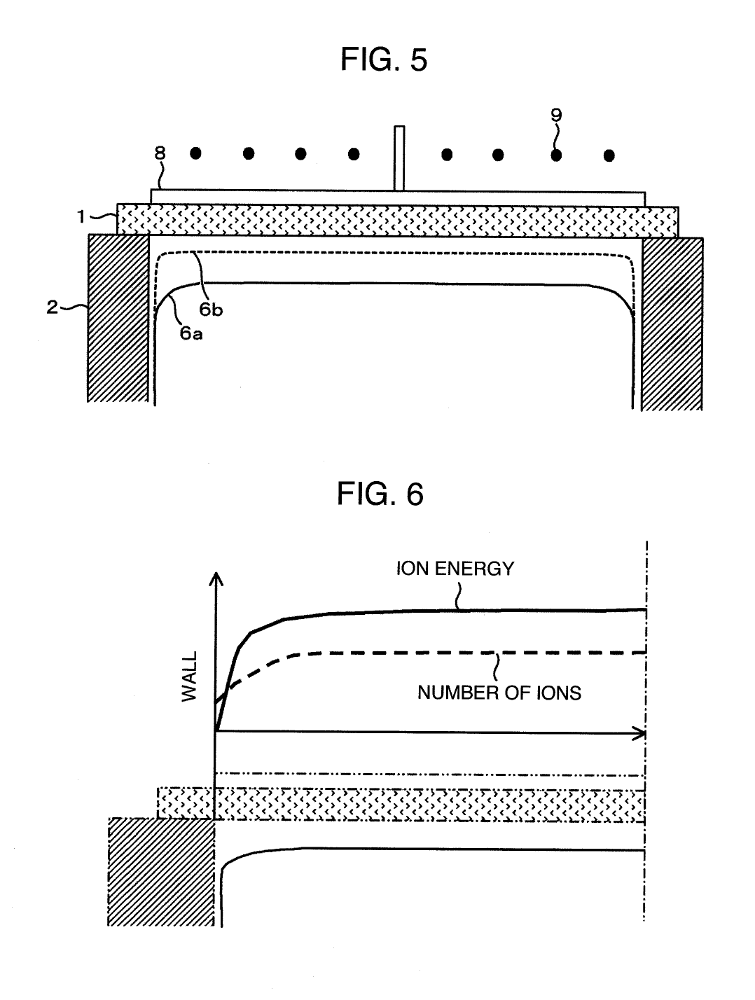

FIG. 5 shows the shapes of the sheaths 6a, 6b formed immediately below the window 1 when various FSV's are applied to the typical Faraday shield 8. When a high FSV of, for example, 1,000 V is applied to the typical Faraday shield 8, the sheath 6a having a flat shape from the Center portion to the Edge portion of the plasma processing chamber and having a round shape, which follows the border portion, in the vicinity of the border part of the Edge portion of the window 1 and the chamber 2 is formed. On the other hand, when a low FSV of, for example, 200 V is applied to the typical Faraday shield 8, the sheath 6b having a flat shape from the Center portion to its Edge portion of the plasma processing chamber and having a round shape, which follows the border portion, in the vicinity of the border part of the Edge portion of the window 1 and the chamber 2 is formed.

The sheath thickness opposing the window 1 of the sheath 6a is greater than that of the sheath 6b. Also, the radius of curvature of the round shape of the sheath 6a is greater than that of the sheath 6b. Therefore, the number of ions coming into the vicinity of the border part of the Edge portion of the window 1 and the chamber 2 is greater in the sheath 6b than in the sheath 6a. However, energy of the ions of the sheath 6b coming into the vicinity of the border part of the Edge portion of the window 1 and the chamber 2 is smaller than that of the sheath 6a.

On the other hand, with regard to the distribution of ion energy in the radial direction of the window 1 and the distribution of the number of ions in the radial direction of the window 1 both the distributions exhibit decreases in the vicinity of the border part of the Edge portion of the window 1 and the chamber 2 as shown in FIG. 6 but the distribution of ion energy decreases more than the distribution of the number of ions. Therefore, it is speculated that the influence of the number of ions is predominant as to the effect of removing the deposits in the vicinity of the border part of the Edge portion of the window 1 and the chamber 2.

Then, it is speculated that the monotonic decrease of the removal rate of the deposits in the vicinity of the border part of the Edge portion of the window 1 and the chamber 2 with the increase of the FSV is because the number of ions coming into the vicinity of the border part of the Edge portion of the window 1 and the chamber 2 decreases when a high FSV is applied to the typical Faraday shield 8 compared with that when a low FSV is applied.

Based on the above, the following means is conceived in order to remove the deposits in the vicinity of the border part of the Edge portion of the window 1 and the chamber 2.

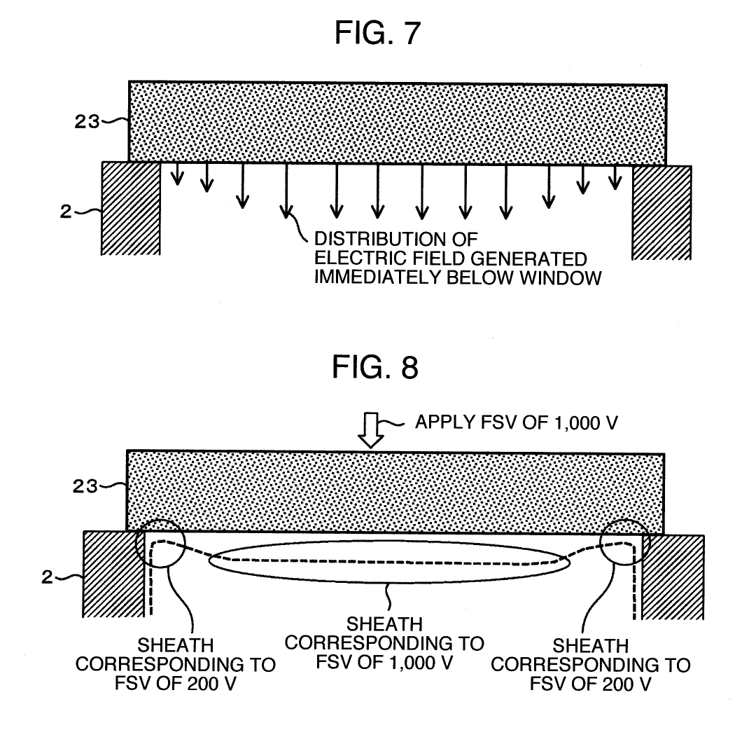

As for the distribution of the electric field generated immediately below the window 1 shown in FIG. 7, the electric field in the vicinity of the border part of the Edge portion of the window 1 and the chamber 2 needs to be smaller than the electric field at the Center portion of the window 1. In other words, a sheath may well be formed in such a fashion that the sheath thickness from the Center portion of the window 1 to the portion in the vicinity of the border part of the Edge portion of the window 1 and the chamber 2 is large and the sheath thickness in the vicinity of the border part of the Edge portion of the window 1 and the chamber 2 is small as shown in FIG. 8.

Namely, a characteristic feature of the present invention is that it has a means for making the sheath thickness at the Edge portion smaller than the sheath thickness at the Center portion. In other words, the characteristic feature of the present invention can also be said that it has a means for making the electrostatic capacity between the Faraday shield and the plasma generated inside the plasma processing chamber at the Edge portion smaller than the electrostatic capacity between the Faraday shield and the plasma generated inside the plasma processing chamber at the Center portion. Further, the present invention can be said to be the invention the characteristic feature of which is to have a means for making the electrostatic capacity between the Faraday shield and the bottom end of the window at the Edge portion smaller than the electrostatic capacity between the Faraday shield and the bottom end of the window at the Center portion.

Hereinafter, specific embodiments of the present invention are explained.

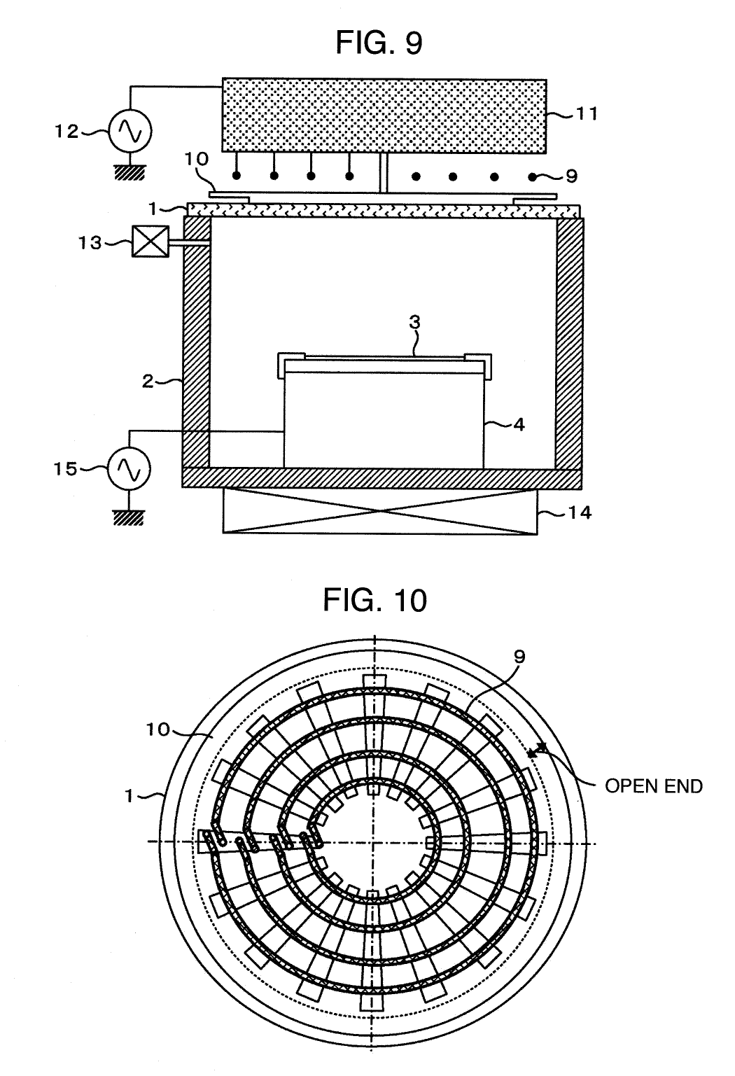

FIG. 9 shows a cross-section of an inductively coupled plasma etching apparatus according to the present invention. The plasma processing chamber includes a window 1 which seals a top part thereof air-tightly, allows an induction magnetic field transmit thereinto, and is a dielectric window made of an insulating material (non-conductive material such as alumina ceramic, for example) and a chamber 2 which includes therein a sample stage 4 on which a sample 3 is mounted. On the upper surface of the window 1 an induction antenna 9 composed of an inner induction antenna of two turns and an outer induction antenna of two turns is arranged as shown in FIG. 10.

Also, between the window 1 and the induction antenna 9 a Faraday shield 10 which is a capacitance electrode for capacitively coupling with plasma is provided. The induction antenna 9 and the Faraday shield 10 are connected in series with a first radio-frequency power supply 12 through a matching box 11, which is a matching device. Further, inside the matching box 11, a variable capacitor and an inductance are mounted.

Therefore, it is possible to make currents split and flow independently through two systems of the inner induction antenna and the outer induction antenna, and the currents and the FSV, which is the radio-frequency voltage applied to the Faraday shield 10, can be controlled. Moreover, a capacitor is also installed in the matching box 11 to suppress reflection of the radio-frequency power of 13.56 MHz, 27.12 MHz, or the like, for example, generated from the first radio-frequency power supply 12.

While a process gas is supplied from a gas supply device 13 into a plasma processing chamber, the process gas supplied into the plasma processing chamber is exhausted to make a pressure in the plasma processing chamber to be a predetermined pressure by an exhaust device 14. The process gas is supplied by the gas supply device 13 into the plasma processing chamber and plasma is generated from the process gas supplied into the plasma processing chamber by action of the induction magnetic field generated from the induction antenna 9 and an electric field generated from the Faraday shield 10. To the sample stage 4, a second radio-frequency power supply 15 is connected. To draw ions present in the plasma in onto the sample 3, radio-frequency bias power is supplied from the second radio-frequency power supply 15 to the sample stage 4.

Next, the construction of the Faraday shield 10 is explained.

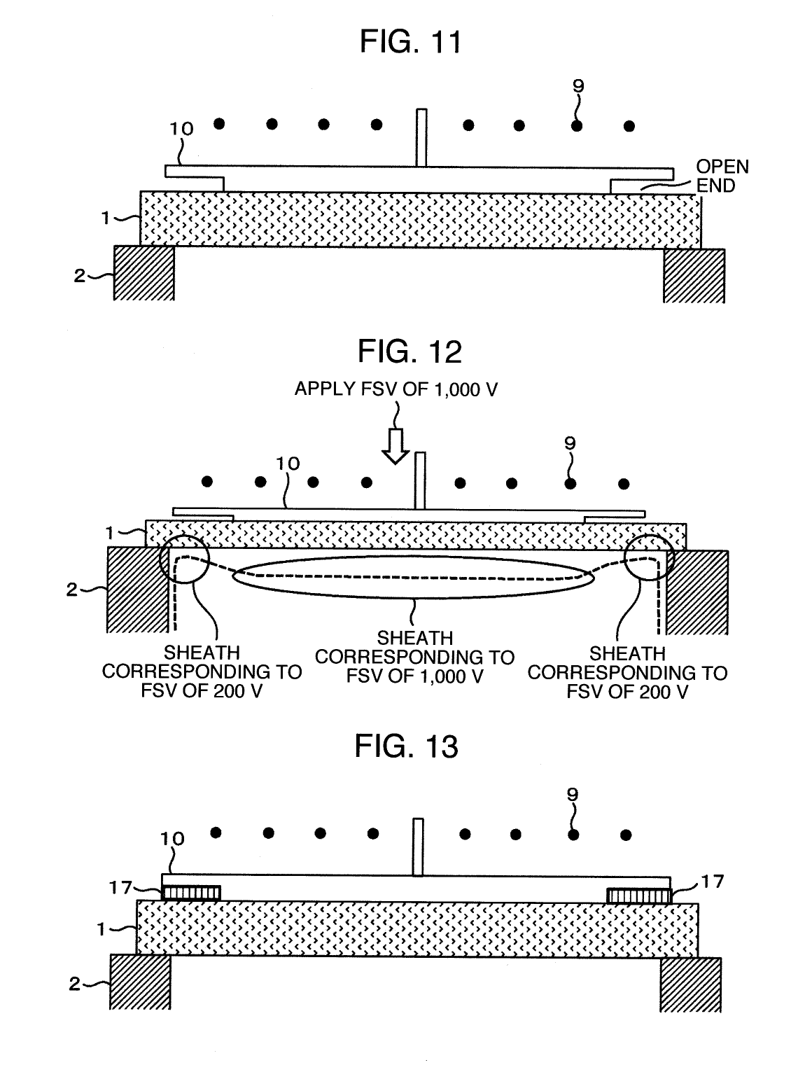

The Faraday shield 10 is a metallic member with slits formed radially from the center to allow the induction magnetic field generated from the induction antenna 9 pass through as shown in FIG. 10. The Faraday shield 10 is a disc-like member with a step, which creates an open end on the opposing side to the window 1, formed on the circumference of the Edge portion as shown in FIG. 11.

The electrostatic capacity between such a Faraday shield 10 and the disc-like window 1 with no step is altered by the step so that the electrostatic capacity at the Edge portion is smaller than the electrostatic capacity at the Center portion because the distance from the lower end of the window 1 to the Faraday shield 10 is greater at the Edge portion than at the Center portion.

Besides, the step of the Faraday shield 10 in the present embodiment is formed so that the capacitance component between the Faraday shield 10 and the window 1 can form at the FSV of 1,000 V a sheath thickness similar to the sheath thickness of the border part of the Edge portion of the window 1 and the chamber 2 when the FSV of 200 V is applied to the typical Faraday shield 8.

In addition, the step of the Faraday shield 10 can be formed to obtain a desired electrostatic capacity but the thickness of the step portion of the Faraday shield 10 needs to be such a thickness that the Faraday shield 10 does not warp by its own weight. When a Faraday shield 10 is produced of a thickness of 10 mm, a diameter of 500 mm, and aluminum as material, for example, the thickness must be 0.0064 mm or more so that it won't warp.

Because the inductively coupled plasma etching apparatus according to the present invention is equipped with the Faraday shield 10 described above, the sheath shape as shown in FIG. 12 can be obtained even when a high FSV of 1,000 V, for example, is applied to the Faraday shield so that the deposits at the border part of the Edge portion of the window 1 and the chamber 2 as shown in FIG. 2 can be removed.

The step of the Faraday shield 10 in the present embodiment is the step the opposing side of which to the window 1 creates an open end; a member of a lower dielectric constant than that of the window 1 may, however, be inserted into the position of the open end as shown in FIG. 13. When the window 1 is made of alumina, polytetrafluoroethylene, for example, may be used for the member. However, the shape of the step in this case needs to be optimized so as to provide a desired electrostatic capacity.

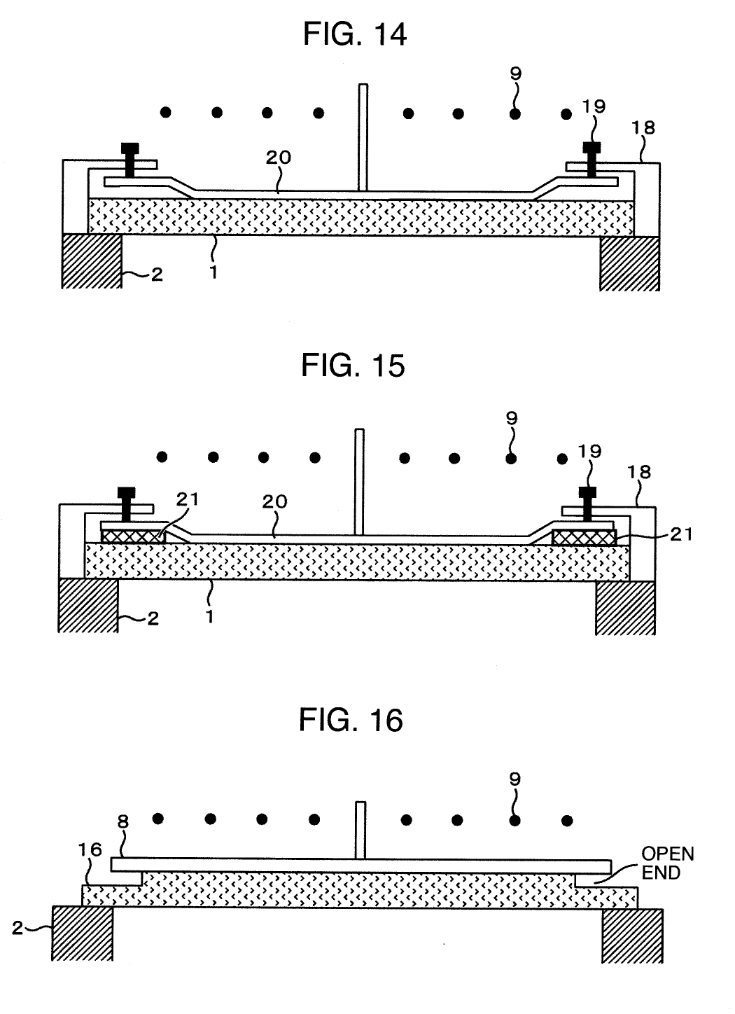

The Faraday shield 10 described above has a shape in which the thickness is different between the Center portion and the Edge portion in the radial direction; however, since the present invention is regarding the means for making the electrostatic capacity between the Faraday shield and the lower end of the window 1 at the Edge portion smaller than the electrostatic capacity between the Faraday shield and the lower end of the window 1 at the Center portion, the Faraday shield 10 does not always need to have a shape in which the thickness is different between the Center portion and the Edge portion in the radial direction and the thicknesses of the Center portion and the Edge portion may be the same. The Faraday shield 20 of this case is a member as shown in FIG. 14 in which, while the thickness of the Faraday shield 20 in the radial direction is the same thickness from the Center portion to the Edge portion, the distance from the Faraday shield 20 to the plasma at the Edge portion is longer than the distance from the Faraday shield 20 to the plasma at the Center portion. Alternatively, the Faraday shield 20 may be a member in which, while the thickness of the Faraday shield 20 in the radial direction is the same from the Center portion to the Edge portion, the distance from the Faraday shield 20 to the lower end of the window 1 at the Edge portion is longer than the distance from the Faraday shield 20 to the lower end of the window 1 at the Center portion.

Furthermore, the distance from the Faraday shield 20 to the plasma at the Edge portion or the distance from the Faraday shield 20 to the lower end of the window 1 at the Edge portion is adjustable in construction with adjusting bolts 19 and a flange 18. Therefore, the electrostatic capacity between the Faraday shield 20 and the plasma at the Edge portion or the electrostatic capacity between the Faraday shield 20 and the lower end of the window 1 at the Edge portion can be controlled easily and with high precision by adjusting the penetration amount of the adjusting bolts 19. Further in this case, the electrostatic capacity may be adjusted with the adjusting bolts 19 and a member 21 while the member 21 of a lower dielectric constant than that of the window 1 is inserted between the Edge portion of the Faraday shield 20 and the window 1 as shown in FIG. 15. However, the shape and the material of the member 21 in this case need to be optimized to achieve a desired electrostatic capacity.

As above, the present invention described so far controls the electrostatic capacity between the Faraday shield and the plasma or the electrostatic capacity between the Faraday shield and the lower end of the window 1 with the Faraday shield; however, the electrostatic capacity between the Faraday shield and the plasma or the electrostatic capacity between the Faraday shield and the lower end of the window 1 can be controlled with the shape of the window. The window 16 in this case is different in thickness at the Center portion and the Edge portion in the radial direction as shown in FIG. 16 and that at the Center portion is thicker than that at the Edge portion. In other words, the window 16 is a disc-like member with a step, the side of which opposing the Faraday shield 8 creates an open end, being formed on the circumference of the Edge portion.

Further, the step of the window 16 in the present embodiment is formed so that the capacitance component between the Faraday shield 8 and the window 16 can form at the FSV of 1,000 V a sheath thickness similar to the sheath thickness of the border part of the Edge portion of the window 1 and the chamber 2 when the FSV of 200V is applied to the typical Faraday shield 8.

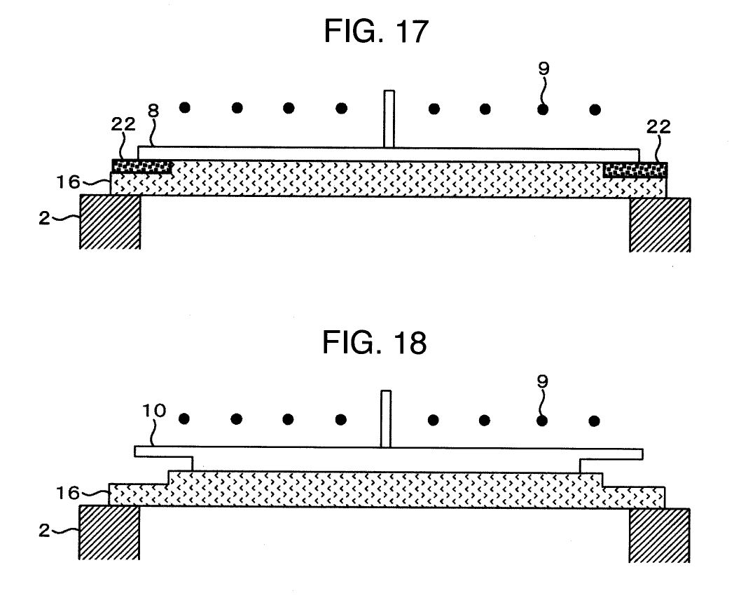

Further in this case, the electrostatic capacity may be controlled by inserting a member 22 of a lower dielectric constant than that of the window 16 between the Edge portion of the window 16 and the Faraday shield 8 as shown in FIG. 17. However, the shape and the material of the member 22 in this case need to be optimized to achieve a desired electrostatic capacity.

As above, in the present embodiment, examples of control of the electrostatic capacity at the Center portion and the Edge portion by the Faraday shield and examples of control of the electrostatic capacity at the Center portion and the Edge portion by the window are explained; however, the Faraday shield 10 and the window 16 may be combined as shown in FIG. 18.

Further, the electrostatic capacity between the Faraday shield and the plasma at the Center portion can be made smaller than the electrostatic capacity between the Faraday shield and the plasma at the Edge portion when the constructions of the Center portion and the Edge portion in the respective embodiments explained in the present embodiments are swapped. Alternatively, the electrostatic capacity between the Faraday shield and the lower end of the window at the Center portion can be made smaller than the electrostatic capacity between the Faraday shield and the lower end of the window at the Edge portion.

Therefore, the present invention is characterized by having a means (electrostatic capacity control means 23) for controlling the electrostatic capacity between the Faraday shield and the plasma at the Center portion and the electrostatic capacity between the Faraday shield and the plasma at the Edge portion. Alternatively, the present invention is characterized by having a means (electrostatic capacity control means 23) for controlling the electrostatic capacity between the Faraday shield and the lower end of the window at the Center portion and the electrostatic capacity between the Faraday shield and the lower end of the window at the Edge portion.

In other words, the present invention has its characteristic feature of having a means for controlling the sheath thickness at the Center portion and the sheath thickness at the Edge portion.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a plasma processing chamber which plasma-processes a sample;
an induction antenna disposed outside said plasma processing chamber;
a radio-frequency power supply which supplies radio-frequency power to said induction antenna; and
a unit which
comprises a Faraday shield capacitively coupled with plasma and a dielectric window which seals an upper part of said plasma processing chamber air-tightly and allows an induction magnetic field generated from said induction antenna transmit into said plasma processing chamber, and
controls electrostatic capacity between said Faraday shield and said dielectric window at a center portion and electrostatic capacity between said Faraday shield and said dielectric window at an edge portion.

2. The plasma processing apparatus according to claim 1, wherein a distance from said Faraday shield to said dielectric window at said center portion and a distance from said Faraday shield to said dielectric window at said edge portion are different from each other.

3. The plasma processing apparatus according to claim 1, wherein a thickness of said dielectric window at said center portion and a thickness of said dielectric window at said edge portion are different from each other.

4. The plasma processing apparatus according to claim 2, wherein said Faraday shield is a disc-like member with a step, a side of which opposing said dielectric window creates an open end, being formed on a circumference of said edge portion.

5. The plasma processing apparatus according to claim 2, wherein a thickness of said dielectric window at said center portion and a thickness of said dielectric window at said edge portion are different from each other.

6. The plasma processing apparatus according to claim 4, wherein a member comprising a dielectric material of a smaller dielectric constant than that of said dielectric window is inserted into said open end of said dielectric window.

7. A plasma processing apparatus comprising:
a plasma processing chamber which plasma-processes a sample;
an induction antenna disposed outside said plasma processing chamber;
a radio-frequency power supply which supplies radio-frequency power to said induction antenna;
a Faraday shield capacitively coupled with plasma; and
a dielectric window which seals an upper part of said plasma processing chamber air-tightly and allows an induction magnetic field generated from said induction antenna transmit into said plasma processing chamber;
wherein a distance from said Faraday shield to said dielectric window at a center portion and a distance from said Faraday shield to said dielectric window at an edge portion are different from each other.

8. The plasma processing apparatus according to claim 7, wherein said Faraday shield is a disc-like member with a step, a side of which opposing said dielectric window creates an open end, being formed on a circumference of said edge portion.

9. A plasma processing apparatus comprising:
a plasma processing chamber which plasma-processes a sample;
an induction antenna disposed outside said plasma processing chamber;
a radio-frequency power supply which supplies radio-frequency power to said induction antenna; and
a unit which controls a sheath thickness of plasma at a center portion and a sheath thickness of plasma at an edge portion.

10. The plasma processing apparatus according to claim 9,
wherein said unit comprises a Faraday shield capacitively coupled with said plasma and a dielectric window which seals an upper part of said plasma processing chamber air-tightly and allows an induction magnetic field generated from said induction antenna transmit into said plasma processing chamber,
and wherein a distance from said Faraday shield to said dielectric window at said center portion and a distance from said Faraday shield to said dielectric window at said edge portion are different from each other.
